(19) United States
(12) Patent Application Publication
(10) Pub. No.: US 2024/0291481 A1
(43) Pub. Date: Aug. 29, 2024

(54) SEMICONDUCTOR DEVICE, SWITCHING POWER SUPPLY DEVICE, DC/DC CONVERTER, VEHICLE, AND MOTOR DRIVE DEVICE

(71) Applicant: ROHM CO., LTD., Kyoto (JP)

(72) Inventor: Isao TAKOBE, Kyoto (JP)

(21) Appl. No.: 18/584,783

(22) Filed: Feb. 22, 2024

(30) Foreign Application Priority Data
Feb. 24, 2023 (JP) 2023-027295

(51) Int. Cl. H03K 17/284; H02M 3/00; H03K 19/003

(52) U.S. Cl. CPC H03K 17/284; H02M 3/003; H03K 19/00315; H03K 2217/0063; H03K 2217/0072

(57) ABSTRACT

A semiconductor device includes: a high-side switching element; a low-side switching element connected in series to the high-side switching element; and a control circuit configured to be capable of controlling on/off operations of the high-side switching element and the low-side switching element in a complementary manner, wherein the semiconductor device is configured to output an output voltage is generated from a voltage at a connection point between the high-side switching element and the low-side switching element, and wherein the control circuit is configured to control a dead time during which both the high-side switching element and the low-side switching element are controlled to be turned off, based on the voltage at the connection point, such that the dead time is shorter when a load that is supplied with the output voltage is heavy than when the load is light.

### CROSS-REFERENCE TO RELATED APPLICATION

This application is based upon and claims the benefit of priority from Japanese Patent Application No. 2023-027295, filed on Feb. 24, 2023, the entire contents of which are incorporated herein by reference.

### TECHNICAL FIELD

The present disclosure relates to a semiconductor device, a switching power supply device, a DC/DC converter, a vehicle, and a motor drive device.

### BACKGROUND

In the related art, in a semiconductor device that operates switching elements connected in series in a complementary manner, it was known to provide a dead time where both switching elements are turned off at the same time to prevent both switching elements from being short-circuited and causing a large current to flow therethrough.

### BRIEF DESCRIPTION OF DRAWINGS

The accompanying drawings, which are incorporated in and constitute a part of the specification, illustrate embodiments of the present disclosure.

FIG. 1 is an overall configuration diagram of a switching power supply device according to an embodiment of the present disclosure.

FIG. 2 is a diagram showing an internal configuration of a high-side drive circuit.

FIG. 3 is a diagram showing an internal configuration of a low-side drive circuit.

FIG. 4 is a timing chart showing an operation of a switching power supply device.

FIG. 5 is a diagram showing a switch voltage when a load is light.

FIG. 6 is a diagram showing a switch voltage when a load is heavy.

FIG. 7 is a timing chart of a high-side drive circuit when a load is light.

FIG. 8 is a timing chart of a high-side drive circuit when a load is heavy.

FIG. 9 is a timing chart of a low-side drive circuit when a load is light.

FIG. 10 is a timing chart of a low-side drive circuit when a load is heavy.

FIG. 11 is a diagram showing an internal configuration of a switching power supply device of a first modification.

FIG. 12 is a diagram showing an internal configuration of a high-side drive circuit of the first modification.

FIG. 13 is a diagram showing an internal configuration of a low-side drive circuit of the first modification.

FIG. 14 is a timing chart of the high-side drive circuit when a load is light.

FIG. 15 is a timing chart of the high-side drive circuit when a load is heavy.

FIG. 16 is a timing chart of the low-side drive circuit when a load is light.

FIG. 17 is a timing chart of the low-side drive circuit when a load is heavy.

FIG. 18 is an overall configuration diagram of a motor drive device using a semiconductor device of a second modification.

FIG. 19 is an external view (front view) of a vehicle equipped with a light emitting device.

FIG. 20 is an external view (rear view) of a vehicle equipped with a light emitting device.

FIG. 21 is an external view of an LED headlight module.

FIG. 22 is an external view of an LED turn lamp module.

FIG. 23 is an external view of an LED rear lamp module.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the present disclosure, a metal oxide semiconductor (MOS) field effect transistor refers to a field effect transistor whose gate structure includes at least three layers, i.e., a “layer made of a conductor or a semiconductor such as polysilicon having a low resistance value,” an “insulating layer,” and a “P-channel type, N-channel type or intrinsic semiconductor layer.” That is, the structure of the gate of the MOS field effect transistor is not limited to the three-layer structure of metal, oxide, and semiconductor.

Examples of embodiments of the present disclosure will be specifically described below with reference to the drawings. In each figure referred to, the same components are designated by the same reference numerals, and overlapping description regarding the same components will be omitted in principle.

First, some terms used in the description of the embodiments of the present disclosure will be explained. “Line” refers to a wiring through which electrical signals are propagated or applied. “Ground” refers to a reference conductive part having a reference potential of 0 V (zero volts) as a reference, or refers to a potential of 0 V itself. The reference conductive part is formed of a conductor such as metal. The potential of 0 V is sometimes referred to as a ground potential. In embodiments of the present disclosure, voltages shown without particular reference represent potentials relative to the ground.

“Level” refers to a level of a potential. For an arbitrary signal or voltage, a high level has a higher potential than a low level. An arbitrary digital signal takes a signal level of a high level or a low level. Regarding an arbitrary signal or voltage of interest, when the signal or voltage is at a high level, it strictly means that the level of the signal or voltage is a high level, and when the signal or voltage is at a low level, it strictly means that the level of the signal or voltage is a low level. The level of a signal may be expressed as a signal level, and the level of a voltage may be expressed as a voltage level. Regarding an arbitrary signal of interest, when the signal is at a high level, an inverted signal thereof has a low level, and when the signal is at a low level, an inverted signal thereof has a high level. Further, the high level may be referred to as a first state.

In an arbitrary signal having a signal level of a high level or a low level, a period during which the level of the signal is a high level is referred to as a high level period. Further, in the same signal, a period during which the level of the signal is a low level is referred to as a low level period. The same applies to an arbitrary voltage that has a voltage level of a high level or a low level.

Regarding an arbitrary transistor configured as a field effect transistor including a MOS field effect transistor, “ON state” refers to a state in which a drain and a source of the transistor are electrically connected to each other. Further, “OFF state” refers to a state (cut-off state) in which the drain and the source of the transistor are not electrically connected to each other. The same applies to transistors that are not classified as field effect transistors. In an arbitrary MOS field effect transistor shown below, it is assumed that a back gate is connected to the source unless otherwise specified.

In the following description, when a switching element is in an on state, both ends of a switch are electrically connected to each other. On the other hand, when a switching element is in an off state, both ends of a switch are not electrically connected to each other. Hereinafter, the on state and off state of a switching element may be simply expressed as turned on and turned off. Further, a period during which a switching element is in an on state may be referred to as an on period, and a period during which a switching element is in an off state may be referred to as an off period. Further, switching from an off state to an on state of a switching element may be referred to as turned on, and switching from an on state to an off state may be referred to as turned off.

“Connection” among multiple components forming a circuit, such as arbitrary circuit elements, wirings (lines), nodes, and the like includes mechanical connection as well as electrical connection, i.e., a state in which a current can flow. In other words, “to connect” includes “to connect electrically.”

### <Switching Power Supply Device A>

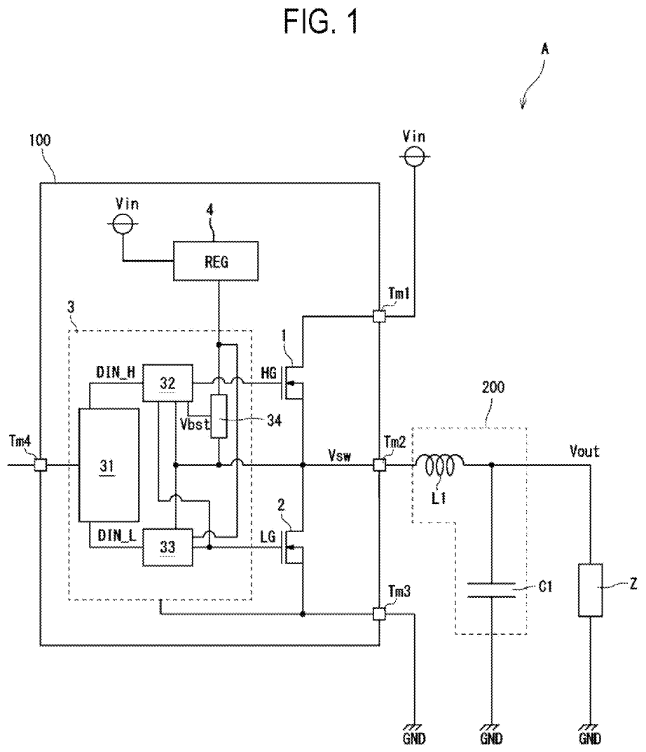

FIG. 1 is an overall configuration diagram of a switching power supply device A according to an embodiment of the present disclosure. The switching power supply device A shown in FIG. 1 includes a step-down DC/DC converter configured to generate an output voltage Vout, which is lower than an input voltage Vin, from the input voltage Vin. The input voltage Vin and the output voltage Vout are positive DC voltages. The switching power supply device A includes a semiconductor device 100 and a smoothing circuit 200.

### <Semiconductor Device 100>

As shown in FIG. 1, the semiconductor device 100 is an integrated circuit (IC) that includes an electric circuit therein and integrates a plurality of electronic elements. The semiconductor device 100 is a half-bridge inverter, and includes a high-side switching element 1, a low-side switching element 2, a control circuit 3, and a power supply circuit 4.

The high-side switching element 1 is an n-channel MOS transistor in the present embodiment. The low-side switching element 2 is an n-channel MOS transistor in the present embodiment. The power supply circuit 4 receives an input voltage Vin and generates a voltage for driving the control circuit 3. For example, the power supply circuit 4 generates a drive voltage Vreg of 5 V from the input voltage Vin of 12 V. In the case of a configuration in which a same current as the drive voltage Vreg for driving the control circuit 3 is supplied as the input voltage Vin, the power supply circuit 4 may be omitted.

The semiconductor device 100 includes a first external connection terminal Tm1, a second external connection terminal Tm2, a third external connection terminal Tm3, and a fourth external connection terminal Tm4 to establish electrical connection with an outside. The first external connection terminal Tm1, the second external connection terminal Tm2, the third external connection terminal Tm3, and the fourth external connection terminal Tm4 themselves have conductivity.

The first external connection terminal Tm1 of the semiconductor device 100 is a terminal to which the input voltage Vin is supplied. A drain of the high-side switching element 1 is connected to the first external connection terminal Tm1 within the semiconductor device 100. That is, the input voltage Vin is supplied to the drain of the high-side switching element 1 via the first external connection terminal Tm1.

In the semiconductor device 100, a source of the high-side switching element 1 and a drain of the low-side switching element 2 are connected at a connection point P1. The connection point P1 is connected to the second external connection terminal Tm2. A switch voltage Vsw is generated at the connection point P1.

A source of the low-side switching element 2 is connected to the third external connection terminal Tm3 within the semiconductor device 100. The third external connection terminal Tm3 of the semiconductor device 100 is connected to the ground potential GND. That is, the source of the low-side switching element 2 is connected to the ground potential GND via the third external connection terminal Tm3.

The second external connection terminal Tm2 is connected to the smoothing circuit 200. The smoothing circuit 200 includes an inductor L1 and a capacitor C1. In the smoothing circuit 200, a first end of the inductor L1 is connected to the second external connection terminal Tm2. In the semiconductor device 100, the connection point P1 is connected to the first end of the inductor L1 via the second external connection terminal Tm2. A second end of the inductor L1 and a first end of the capacitor C1 are connected to a load Z. As shown in FIG. 1, a switch voltage Vsw of the semiconductor device 100 is rectified and smoothed by the smoothing circuit 200, and is supplied to the load Z as the output voltage Vout. An inductor current IL flows through the inductor L1.

In the semiconductor device 100, the control circuit 3 controls the high-side switching element 1 and the low-side switching element 2 to be turned on and off in a complementary manner, thereby lowering the input voltage Vin to the switch voltage Vsw. “Complementary” refers to a state in which the on state and off state of the high-side switching element 1 and the low-side switching element 2 are alternately switched. To explain further, “complementary” includes not only a complete switching but also, for example, a dead time during which both the high-side switching element 1 and the low-side switching element 2 are turned off.

The control circuit 3 supplies a high-side drive signal HG to a gate of the high-side switching element 1 and supplies a low-side drive signal LG to a gate of the low-side switching element 2. The high-side switching element 1 is in an on state when the high-side drive signal HG is at a high level, and is in an off state when the high-side drive signal HG is at a low level. Further, the low-side switching element 2 is in an on state when the low-side drive signal LG is at a high level, and is in an off state when the low-side drive signal LG is at a low level.

The control circuit 3 includes a signal generation circuit 31, a high-side drive circuit 32, a low-side drive circuit 33, and a bootstrap circuit 34.

The signal generation circuit 31 supplies a high-side command signal DIN_H to the high-side drive circuit 32 under pulse width modulation (PWM) control. Further, the control circuit 3 supplies a low-side command signal DIN_L to the low-side drive circuit 33. The high-side command signal DIN_H and the low-side command signal DIN_N are signals controlled to a high level or a low level.

The high-side command signal DIN_H is at a high level during a period when the high-side switching element 1 is controlled to be turned on. The low-side command signal DIN_L is at a high level during a period when the low-side switching element 2 is controlled to be turned on. That is, the high-side command signal DIN_H and the low-side command signal DIN_L are signals that determine the on/off period of the high-side switching element 1 and the low-side switching element 2 so as not to include a dead time. Considering that a dead time is included, it may be said that the high-side command signal DIN_H is at a high level during the period when the low-side switching element 2 is turned off. Further, it may be said that the low-side command signal DIN_L is at a high level during the period when the high-side switching element 1 is turned off.

The high-side drive circuit 32 supplies a high-side drive signal HG to the gate of the high-side switching element 1 based on the high-side command signal DIN_H. The low-side drive circuit 33 supplies a low-side drive signal LG to the gate of the low-side switching element 2 based on the low-side command signal DIN_L. Details of the high-side drive circuit 32 and the low-side drive circuit 33 will be described later.

The bootstrap circuit 34 supplies a bootstrap voltage Vbst to the high-side drive circuit 32. The bootstrap circuit 34 is a circuit configured to generate a voltage necessary for driving the high-side switching element 1. The bootstrap circuit 34 is a well-known circuit, and detailed description thereof will be omitted.

### <High-Side Drive Circuit 32>

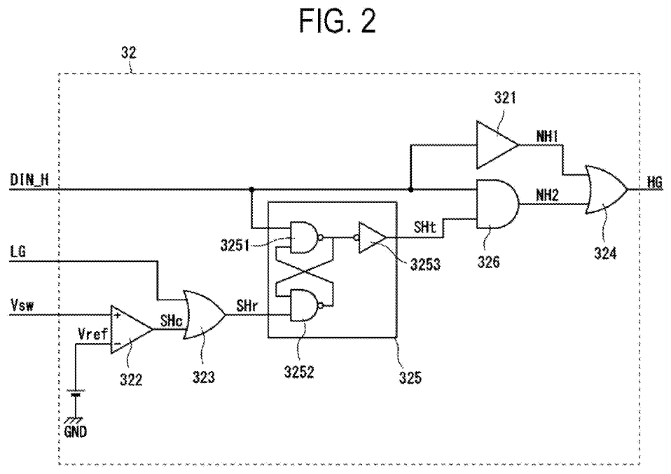

The high-side drive circuit 32 will be described with reference to the drawings. FIG. 2 is a diagram showing an internal configuration of the high-side drive circuit 32. As shown in FIG. 2, the high-side drive circuit 32 receives the high-side command signal DIN_H, the low-side drive signal LG that controls the low-side switching element 2 to be turned on and off, and a switch voltage Vsw from the signal generation circuit 31.

As shown in FIG. 2, the high-side drive circuit 32 includes a high-side delay circuit 321, a high-side comparison circuit 322, a first high-side OR circuit 323, a second high-side OR circuit 324, an RS latch circuit 325, and a high-side AND circuit 326.

The high-side delay circuit 321 delays the high-side command signal DIN_H for a certain period. The period for which the high-side delay circuit 321 delays the high-side command signal DIN_H is referred to as a first high-side delay time Td1. The high-side delay circuit 321 is an on delay circuit, and is configured to delay a timing at which the high-side command signal DIN_H is switched from a low level to a high level. Then, the high-side delay circuit 321 outputs a first high-side control signal NH1 obtained by delaying the timing of switching the high-side command signal DIN_H from a low level to a high level by the first high-side delay time Td1. Details of the first high-side delay time Td1 will be described later.

A switch voltage Vsw is supplied to an inverting input terminal of the high-side comparison circuit 322. Further, a reference voltage Vref is supplied to a non-inverting input terminal of the high-side comparison circuit 322. The high-side comparison circuit 322 outputs a comparison result signal SHc based on a result of comparison of the switch voltage Vsw and the reference voltage Vref. That is, the comparison result signal SHc is at a high level when the switch voltage Vsw is higher than the reference voltage Vref. In the semiconductor device 100 of the present embodiment, the reference voltage Vref is half of the drive voltage Vreg for driving the control circuit 3. However, the reference voltage Vref is not limited thereto, and may be a separately set voltage.

The first high-side OR circuit 323 receives the low-side drive signal LG for driving the low-side switching element 2 and the comparison result signal SHc as input signals, and outputs a reset signal SHr. The first high-side OR circuit 323 outputs the reset signal SHr at a high level when at least one selected from the group of the low-side drive signal LG and the comparison result signal SHc is at a high level. That is, the reset signal SHr is at a high level when at least one selected from the group of the low-side drive signal LG and the comparison result signal SHc is at a high level.

In the RS latch circuit 325, the high-side command signal DIN_H is input to a set terminal, the reset signal SHr is input to a reset terminal, and a high-side delay time determination signal SHt is output. The high-side delay time determination signal SHt is at a high level when the high-side command signal DIN_H is at a high level and the reset signal SHr is at a low level.

Specifically, the RS latch circuit 325 includes two NAND circuits 3251 and 3252 and a NOT circuit 3253. The NAND circuit 3251 receives the high-side command signal DIN_H and an output signal of the NAND circuit 3252 as two input signals, and outputs an output signal of a high level when at least one selected from the group of the high-side command signal DIN_H and the output signal of the NAND circuit 3252 is at a low level. Further, the NAND circuit 3252 receives the reset signal SHr and the output signal of the NAND circuit 3251 as two input signals, and outputs an output signal of a high level when at least one selected from the group of the reset signal SHr and the output signal of the NAND circuit 3251 is at a low level.

The output signal of the NAND circuit 3251 is input to the NOT circuit 3253. The output signal of the NOT circuit 3253 is a high-side delay time determination signal SHt. That is, the RS latch circuit 325 outputs the high-side delay time determination signal SHt of a high level when the high-side command signal DIN_H is at a high level and the reset signal SHr is at a low level. Further, when the reset signal SHr is at a high level, the RS latch circuit 325 outputs the high-side delay time determination signal SHt of a low level. The high-side delay time determination signal SHt is a signal for determining a length of a dead time.

The high-side AND circuit 326 receives the high-side command signal DIN_H and the high-side delay time determination signal SHt as input signals, and outputs a second high-side control signal NH2. The high-side AND circuit 326 outputs the second high-side control signal NH2 of a high level when both the high-side command signal DIN_H and the high-side delay time determination signal SHt are at a high level. The second high-side control signal NH2 is at a high level when both the high-side command signal DIN_H and the high-side delay time determination signal SHt are at a high level.

The second high-side OR circuit 324 receives the first high-side control signal NH1 and the second high-side control signal NH2 as input signals, and outputs a high-side drive signal HG. The second high-side OR circuit 324 outputs the high-side drive signal HG of a high level when at least one selected from the group of the first high-side control signal NH1 and the second high-side control signal NH2 is at a high level. The high-side drive signal HG is at a high level when at least one selected from the group of the first high-side control signal NH1 and the second high-side control signal NH2 is at a high level.

### <Low-Side Drive Circuit 33>

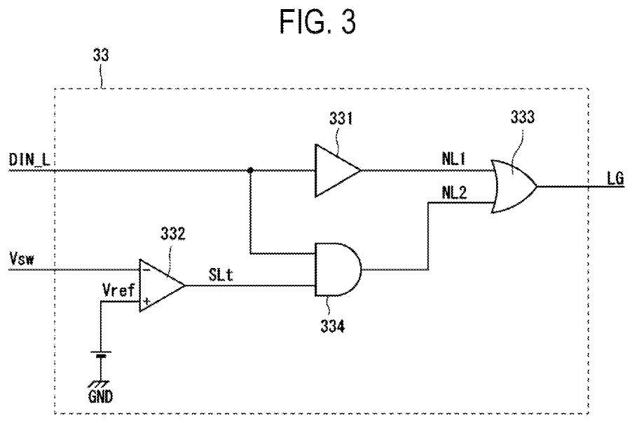

The low-side drive circuit 33 will be described with reference to the drawings. FIG. 3 is a diagram showing an internal configuration of the low-side drive circuit 33. As shown in FIG. 3, the low-side command signal DIN_L from the signal generation circuit 31 and the switch voltage Vsw are input to the low-side drive circuit 33.

As shown in FIG. 3, the low-side drive circuit 33 includes a low-side delay circuit 331, a low-side comparison circuit 332, a low-side OR circuit 333, and a low-side AND circuit 334.

The low-side delay circuit 331 delays the low-side command signal DIN_L for a certain period. The period for which the low-side delay circuit 331 delays the low-side command signal DIN_L is referred to as a first low-side delay time Tf1. The low-side delay circuit 331 is an on delay circuit, and is configured to delay the timing at which the low-side command signal DIN_L is switched from a low level to a high level. Then, the low-side delay circuit 331 outputs a first low-side control signal NL1 obtained by delaying the timing of switching the low-side command signal DIN_L from a low level to a high level by the first low-side delay time Tf1. The first low-side control signal NL1 is input to the low-side OR circuit 333 together with a second low-side control signal NL2, which will be described later.

A reference voltage source 335 is connected to an inverting input terminal of the low-side comparison circuit 332, and a reference voltage Vref generated by the reference voltage source 335 is supplied to the low-side comparison circuit 332. The reference voltage Vref is the same as the reference voltage Vref supplied to the high-side comparison circuit 322, but may be a different voltage. Further, a switch voltage Vsw is supplied to the non-inverting input terminal of the low-side comparison circuit 332. The low-side comparison circuit 332 outputs a low-side delay time determination signal SLt based on the result of comparison of the switch voltage Vsw and the reference voltage Vref. That is, the low-side delay time determination signal SLt is at a high level when the switch voltage Vsw is lower than the reference voltage Vref.

The low-side AND circuit 334 receives the low-side command signal DIN_L and the high-side delay time determination signal SHt as input signals, and outputs a second low-side control signal NL2. The low-side AND circuit 334 outputs the second low-side control signal NL2 of a high level when both the low-side command signal DIN_L and the low-side delay time determination signal SLt are at a high level. The second low-side control signal NL2 is at a high level when both the low-side command signal DIN_L and the low-side delay time determination signal SLt are at a high level.

The low-side OR circuit 333 receives the first low-side control signal NL1 and the second low-side control signal NL2 as input signals, and outputs a low-side drive signal LG. The low-side OR circuit 333 outputs the low-side drive signal LG of a high level when at least one selected from the group of the first low-side control signal NL1 and the second low-side control signal NL2 is at a high level. The low-side drive signal LG is at a high level when at least one selected from the group of the first low-side control signal NL1 and the second low-side control signal NL2 is at a high level.

### <Operation of Switching Power Supply Device A>

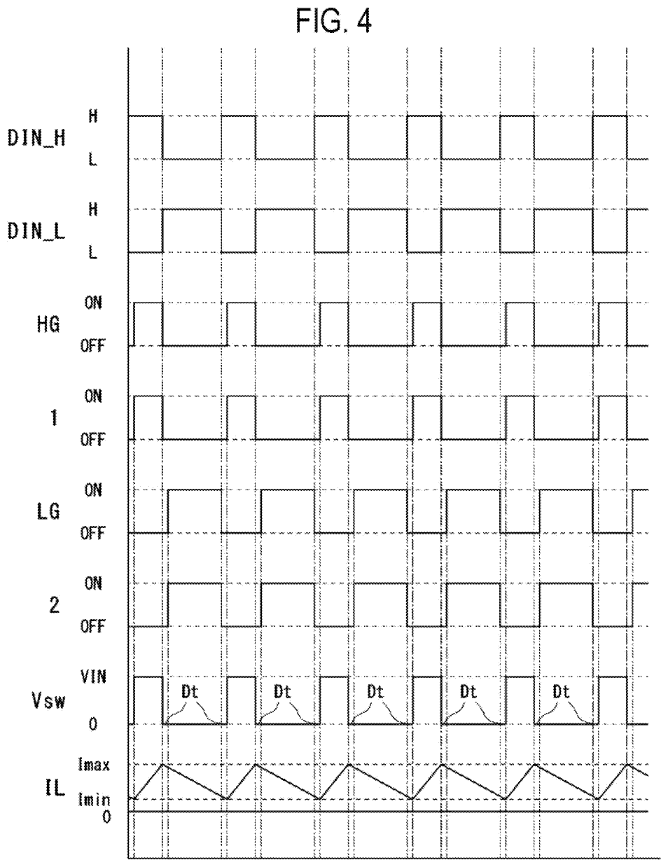

The switching power supply device A has a configuration described above. Next, an operation of the switching power supply device A will be described with reference to the drawings. FIG. 4 is a timing chart showing the operation of the switching power supply device A. FIG. 4 shows states of the high-side command signal DIN_H, the low-side command signal DIN_L, the high-side drive signal HG, the low-side drive signal LG, the operations of the high-side switching element 1 and the low-side switching element 2, the switch voltage Vsw, and the inductor current IL flowing through the inductor L1. The switching power supply device A is a synchronous rectification type switching power supply device in which the high-side switching element 1 and the low-side switching element 2 operate synchronously to rectify an input voltage.

In the switching power supply device A, the output voltage Vout is determined by the length of the on period of the high-side switching element. The signal generation circuit 31 of the control circuit 3 determines the high level period of the high-side command signal DIN_H based on the on period of the high-side switching element 1. Further, the signal generation circuit 31 determines the low-side command signal DIN_L such that when the high-side command signal DIN_H is in a low level period, the low-side command signal DIN_L is in a high level period.

As shown in FIG. 4, when one of the high-side command signal DIN_H and the low-side command signal DIN_L is in a high level period, the other is in a low level period. The high-side switching element 1 and the low-side switching element 2 are turned on or turned off based on the drive signal. When the high-side switching element 1 and the low-side switching element 2 are turned on or turned off, a delay may occur. This delay may lead to a short-circuited state.

The control circuit 3 provides a dead time period Dt (see FIG. 4) to prevent the high-side switching element 1 and the low-side switching element 2 from be short-circuited. That is, the high-side drive circuit 32 and the low-side drive circuit 33 generate the high-side drive signal HG and the low-side drive signal LG such that the dead time period Dt occurs from the high-side command signal DIN_H and the low-side command signal DIN_L.

On the other hand, in the switching power supply device A using a synchronous rectification step-down DC/DC converter, when both the high-side switching element 1 and the low-side switching element 2 are turned off, losses (dead time losses Pd1 and Pd2) are generated due to a forward voltage of a body diode of the low-side switching element 2 and a load current. Now, the loss during the dead time period Dt of the switching power supply device A will be described. During the dead time period Dt in the switching power supply device A, when both the high-side switching element 1 and the low-side switching element 2 are turned off, the dead time losses Pd1 and Pd2 due to a parasitic diode of the low-side switching element 2 change depending on whether the load Z is heavy or light. The loss due to the dead time period when the switch voltage Vsw rises is assumed to be Pd1, and the loss due to the dead time period when the switch voltage Vsw falls is assumed to be Pd2.

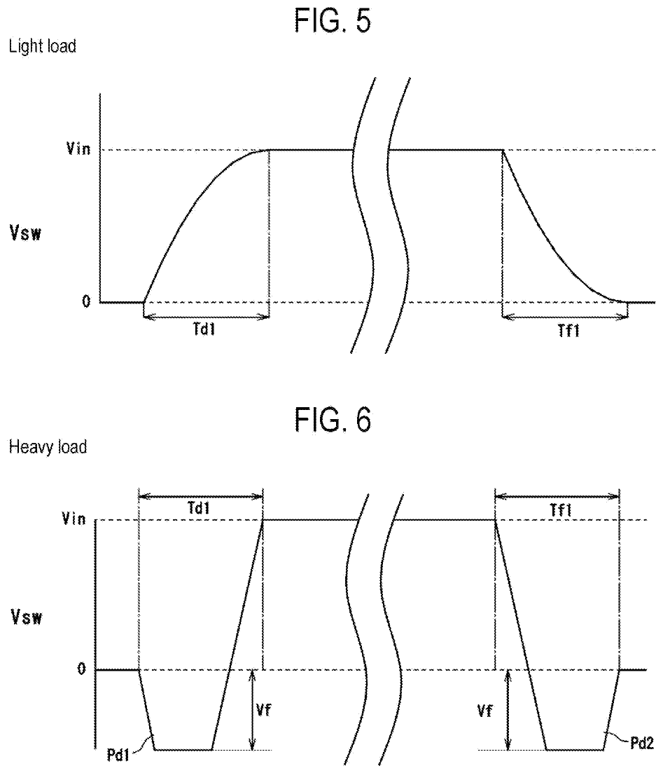

FIG. 5 is a diagram showing the switch voltage Vsw when the load Z is light. FIG. 6 is a diagram showing the switch voltage Vsw when the load Z is heavy. The expression “load Z is light” indicates that the load is in a zero voltage switching (ZVS) operation in which Vsw is raised by a regenerative current of the inductor L1 during the dead time period Dt. Further, the expression “load Z is heavy” indicates that the load Z is heavier than a light load.

As shown in FIG. 5, when the switch voltage Vsw is changed from 0 to Vin (this change is defined as the rise of the switch voltage Vsw), the switch voltage Vsw begins to decrease at the moment when the low-side switching element 2 is turned off, in other words, when the low-side drive signal LG reaches a certain level or below.

In a case where the switch voltage Vsw rises when the load Z is light, the ZVS operation is performed during the dead time period Dt. Therefore, the switch voltage Vsw at the time of rising gradually increases and becomes the input voltage Vin at the end of the dead time period Dt. Therefore, the dead time loss Pd1 is not generated. A length Td of the dead time period Dt set such that the ZVS operation is performed is a first high-side delay time Td1. The first high-side delay time Td1 needs to be long to some extent so as to prevent the dead time loss Pd1 from being generated when a light load Z is connected.

As shown in FIG. 5, when the switch voltage Vsw for the light load Z is changed from Vin to 0 (this change is defined as a fall of the switch voltage Vsw), the switch voltage Vsw begins to decrease at the moment when the high-side switching element 1 is turned off, in other words, when the high-side drive signal HG reaches a certain level or below.

Even in a case where the switch voltage Vsw falls when the load Z is light, the dead time period Dt is determined such that the ZVS operation is performed. A length Tf of the dead time period Dt set such that the ZVS operation is performed is a first low-side delay time Tf1. The first low-side delay time Tf1 needs to be long to some extent so as to prevent the dead time loss Pd2 from being generated when the light load Z is connected.

On the other hand, during the dead time period Dt at the rising time, in a case where the load Z is a heavy load, when the high-side switching element 1 and the low-side switching element 2 are turned off, the switch voltage Vsw is lowered by the regenerative current of the inductor L1. A drain voltage of the low-side switching element 2 becomes lower than a source voltage. A source-drain voltage becomes the forward voltage Vf of the body diode of the low-side switching element 2. At this time, a current flows through the low-side switching element 2 from the source to the drain. A loss (dead time loss) is generated in the low-side switching element 2 due to the forward voltage Vf and the current.

When a GaN device is used, there is no body diode. However, when the gate voltage becomes higher than the drain voltage and exceeds a threshold value, a channel is formed to act like a body diode, allowing a current to flow from the source to the drain. The source-drain voltage at this time is also assumed to be the forward voltage Vf. The dead time loss Pd is expressed by the following formula:

$$Pd 1 = Td \times Vf \times IL \times Fsw$$

where Td is the length of the dead time period and Fsw is a switching frequency. When the load Z is heavy, it is possible to reduce the dead time loss Pd by shortening the first high-side delay time Td1.

Similarly, at the time of falling, in a case where the load Z is heavy during the dead time period Dt, when the high-side switching element 1 and the low-side switching element 2 are turned off, the switch voltage Vsw is lowered by the regenerative current of the inductor L1. The drain voltage of the low-side switching element 2 becomes lower than the source voltage thereof. This source-drain voltage becomes the forward voltage Vf of the body diode of the low-side switching element 2. At this time, a current flows through the low-side switching element 2 from the source to the drain. A loss (dead time loss) is generated in the low-side switching element 2 due to the forward voltage Vf and the current.

Regarding GaN, as described above, the source-drain voltage when the channel is formed is assumed to be the forward voltage Vf. At this time, the dead time loss Pd is expressed by the following formula:

$$Pd 2 = Tf \times Vf \times IL \times Fsw$$

where Tf is the length of the dead time period and Fsw is the switching frequency. When the load Z is heavy, it is possible to reduce the dead time loss Pd by shortening the first low-side delay time Tf1.

Since the control circuit 3 includes the high-side drive circuit 32 and the low-side drive circuit 33, the dead time loss can be kept low regardless of whether the load Z is light or heavy. Now, details of operations of the high-side drive circuit 32 and the low-side drive circuit 33 will be described with reference to the drawings. First, generation of the high-side drive signal HG by the high-side drive circuit 32 will be described with reference to the drawings.

### <Operation of High-Side Drive Circuit 32>

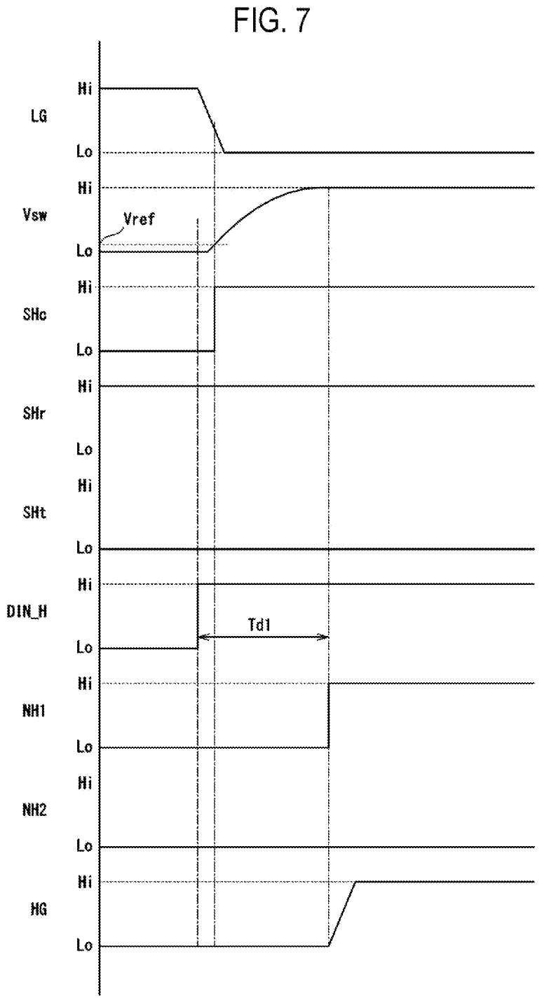

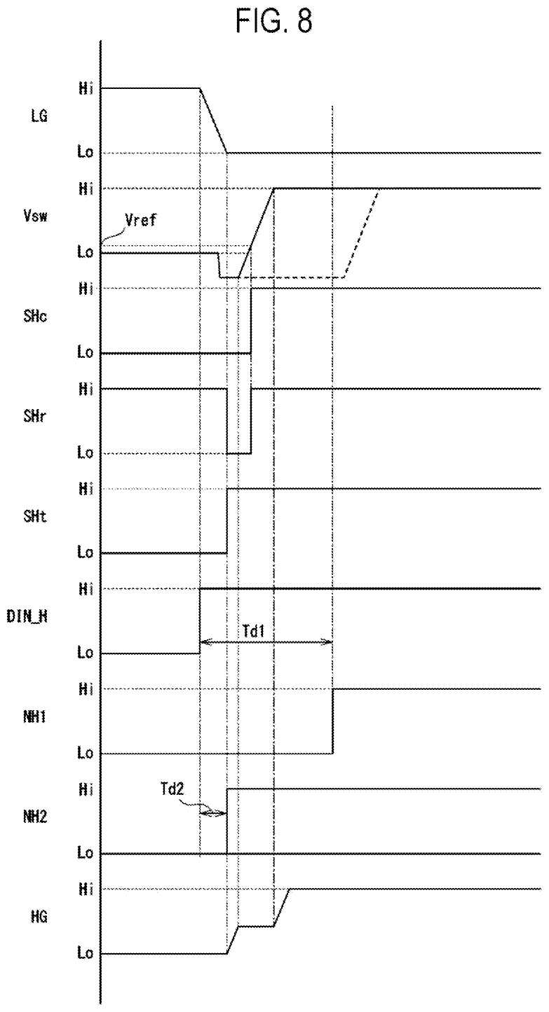

FIG. 7 is a timing chart of the high-side drive circuit 32 when the load Z is light. FIG. 8 is a timing chart of the high-side drive circuit 32 when the load Z is heavy. The high-side drive circuit 32 is a circuit configured to control the operation of the high-side switching element 1, and the dead time determined by the high-side drive circuit 32 is a dead time when the switch voltage Vsw rises.

Further, the low-side delay circuit 331 of the low-side drive circuit 33 does not delay the low-side command signal DIN_L when it is changed from a high level to a low level. That is, as soon as the low-side command signal DIN_L falls to the low level, the low-side drive signal LG begins to fall to the low level.

In the high-side drive circuit 32, the reference voltage Vref is set on the assumption that the switch voltage Vsw is not raised by the regenerative current of the inductor L1. In the high-side drive circuit 32 of the present embodiment, half of the drive voltage Vreg of the control circuit 3 is assumed. However, the reference voltage Vref is not limited to this value. It may be possible to adopt a wide range of voltages that can suppress the rise of the switch voltage Vsw due to the regenerative current of the inductor L1.

First, when the high-side command signal DIN_H of a high level is input to the high-side drive circuit 32, the high-side delay circuit 321 outputs a first high-side control signal NH1 obtained by delaying a time required for rising to the high level by the first high-side delay time Td1.

When a light load Z is connected, the switch voltage Vsw increases gradually. The increase is started before the low-side drive signal LG reaches a low level. Then, after the high-side command signal DIN_H is switched to a high level, the switch voltage Vsw becomes higher than the reference voltage Vref in the high-side comparison circuit 322. As a result, a comparison result signal SHc of a high level is output. As shown in FIG. 7, a timing at which the switch voltage Vsw becomes higher than the reference voltage Vref is before the low-side drive signal LG becomes a low level.

As a result, at least one selected from the group of the low-side drive signal LG and the comparison result signal SHc input to the first high-side OR circuit 323 is at a high level. Therefore, the first high-side OR circuit 323 continues to output a reset signal Shr of a high level (see FIG. 7).

At this time, the high-side command signal DIN_H of a high level is input to the set terminal of the RS latch circuit 325, and the reset signal SHr of a high level is input to the reset terminal of the RS latch circuit 325. As a result, the RS latch circuit 325 continues to output the high-side delay time determination signal SHt of the low level.

The high-side AND circuit 326 receives the high-side command signal DIN_H of the high level and the high-side delay time determination signal SHt of the low level. As a result, the high-side AND circuit 326 outputs a second high-side control signal NH2 of a low level.

The second high-side OR circuit 324 receives the first high-side control signal NH1 and the second high-side control signal NH2. The second high-side control signal NH2 is at a low level. Further, the first high-side control signal NH1 is switched to a high level after the high-side command signal DIN_H is switched to a high level and the first high-side delay time Td1 has elapsed.

Therefore, the second high-side OR circuit 324 outputs the high-side drive signal HG of the low level until the high-side command signal DIN_H is switched to a high level and the first high-side delay time Td1 has elapsed. Then, the second high-side OR circuit 324 outputs the high-side drive signal HG of the high level after the high-side command signal DIN_H is switched to a high level and the first high-side delay time Td1 has elapsed (see FIG. 7).

In the switching power supply device A, the control circuit 3 is configured such that when the connected load Z is light and after the predetermined first high-side delay time Td1 has elapsed, the high-side drive signal HG is switched to a high level and the high-side switching element 1 is turned on. The high-side drive circuit 32 outputs the high-side drive signal HG so that the length of the dead time period Dt is set to the predetermined first high-side delay time Td1.

Next, the operation of the high-side drive circuit 32 when the load Z is heavy will be described. As shown in FIG. 8, the first high-side control signal NH1 output by the high-side delay circuit 321 is the same as that when the load is light.

As shown in FIG. 8, when the low-side drive signal LG is at a high level, the switch voltage Vsw is lower than the reference voltage Vref. Therefore, in the high-side drive circuit 32, while the low-side drive signal LG is at the high level, the high-side comparison circuit 322 continues to output the comparison result signal SHc of the low level. The comparison result signal SHc is maintained at the low level until the switch voltage Vsw rises and becomes higher than the reference voltage Vref.

Then, the low-side drive signal LG starts falling at the same time as the high-side command signal DIN_H becomes a high level. As shown in FIG. 8, the low-side drive signal LG sequentially decreases from a high level to a low level over a certain period of time. The first high-side OR circuit 323 may be a circuit in which it is assumed that the low-side drive signal LG has been switched to a low level when it becomes lower than a certain level.

The first high-side OR circuit 323 receives the low-side drive signal LG of the high level and the comparison result signal SHc of the low level until the low-side drive signal LG reaches a low level. As a result, the first high-side OR circuit 323 outputs a reset signal SHr of a high level when the low-side drive signal LG is at the high level, and outputs a reset signal SHr of a low level when the low-side drive signal LG is switched to a low level. When it is confirmed that the low-side drive signal LG is at a low level and that the switch voltage Vsw is equal to or lower than the reference voltage Vref, the first high-side OR circuit 323 outputs a reset signal SHr of a low level.

The high-side command signal DIN_H is input to the set terminal of the RS latch circuit 325, and the reset signal SHr is input to the reset terminal. In FIG. 8, the high-side command signal DIN_H is at a high level, and the reset signal SHr is initially at a high level. Therefore, while the reset signal SHr is at the high level, the RS latch circuit 325 outputs a high-side delay time determination signal SHt of a low level. Then, when the reset signal SHr becomes a low level, i.e., when the switch voltage Vsw is equal to the reference voltage Vref, and when the low-side drive signal LG is switched to a low level, the RS latch circuit 325 outputs the high-side delay time determination signal SHt of a high level.

The high-side AND circuit 326 receives the high-side command signal DIN_H of the high level and the high-side delay time determination signal SHt switched from a low level to a high level. As a result, the high-side AND circuit 326 outputs a second high-side control signal NH2 switched from a low level to a high level.

The second high-side OR circuit 324 receives the first high-side control signal NH1 and the second high-side control signal NH2. The second high-side control signal NH2 is switched from a low level to a high level.

Therefore, the second high-side OR circuit 324 outputs a high-side drive signal HG which is switched from a low level to a high level as the first high-side control signal NH1 is switched to a high level or as the second high-side control signal NH2 is switched to a high level. As described above, when the load Z is heavy, the second high-side control signal NH2 is switched from a low level to a high level at the timing at which the low-side drive signal LG completely reaches the low level.

Since the high-side drive signal HG is a gate voltage that drives the high-side switching element 1, a plateau region in which the high-side drive signal HG remains at a constant voltage level is generated until the switch voltage Vsw rises to a constant voltage. Similarly, even when the switch voltage Vsw drops, a plateau region in which the high-side drive signal HG remains at a constant voltage level is generated.

The high-side switching element 1 is turned on when the high-side drive signal HG reaches a voltage level equal to or higher than a certain level. In the same manner as the fall of the low-side drive signal LG, the rise of the high-side drive signal HG also increases sequentially over a certain period of time. Therefore, even in a case where the high-side drive signal HG is controlled to start rising when the low-side drive signal LG completely reaches the low level, it is possible to secure a dead time period Dt during which the high-side switching element 1 and the low-side switching element 2 are turned off at the same time. The second high-side delay time Td2 is a time from when the high-side command signal DIN_H is switched to a high level to when the low-side drive signal LG starts to be completely switched to a low level.

As shown in FIG. 8, in a case where the load Z is heavier than when the load is a light load, the second high-side delay time Td2 of the switch voltage Vsw is shorter than the first high-side delay time Td1. In other words, the high-side drive circuit 32 is configured to make the second high-side delay time Td2 shorter than the first high-side delay time Td1 by the feature that the switch voltage Vsw is lowered by the regenerative current of the inductor L1 when the load is heavy.

That is, the high-side drive circuit 32 outputs a high-side drive signal HG that sets the length of the dead time period Dt to a second high-side delay time Td2 shorter than a predetermined first high-side delay time Td1.

As a result, the term of the length of the dead time period Td in the above-mentioned formula for the dead time loss Pd1 is substituted by the second high-side delay time Td2 which is shorter than the first high-side delay time Td1. This makes it possible to reduce the dead time loss Pd1.

As described above, since the control circuit 3 uses the high-side drive circuit 32, it is possible to reduce the dead time loss when the switch voltage Vsw of the switching power supply device A rises, regardless of the load Z.

### <Operation of Low-Side Drive Circuit 33>

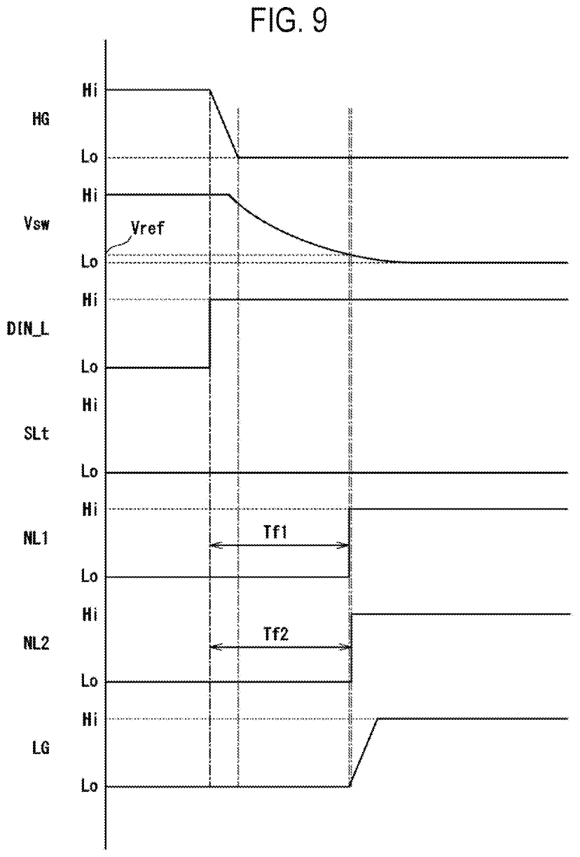

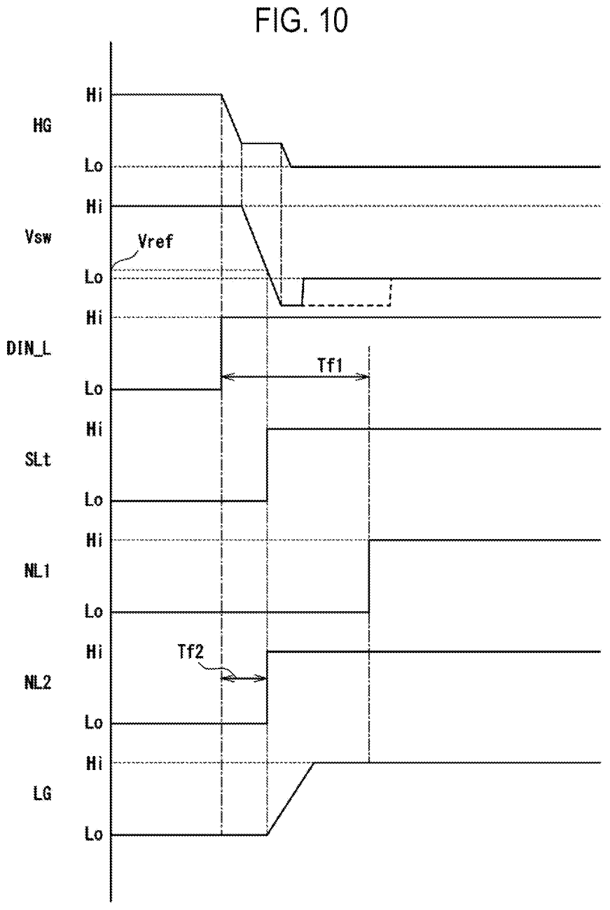

FIG. 9 is a timing chart of the low-side drive circuit 33 when the load Z is light. FIG. 10 is a timing chart of the low-side drive circuit 33 when the load Z is heavy. The low-side drive circuit 33 is a circuit configured to control the operation of the low-side switching element 2. The dead time determined by the low-side drive circuit 33 is a dead time when the switch voltage Vsw falls.

Further, the high-side delay circuit 321 of the high-side drive circuit 32 does not perform delay when the high-side command signal DIN_H is changed from a high level to a low level. That is, as soon as the high-side command signal DIN_H falls to the low level, the high-side drive signal HG begins to fall to the low level.

In the low-side drive circuit 33 as well, the reference voltage Vref is set to half of the drive voltage Vreg. However, the present disclosure is not limited thereto.

First, when the low-side command signal DIN_L of the high level is input to the low-side drive circuit 33, the low-side delay circuit 331 outputs a first low-side control signal NL1 whose rising time to high level is delayed by the first low-side delay time Tf1.

When a light load Z is connected, the switch voltage Vsw gradually decreases. Therefore, after the low-side command signal DIN_L is switched to a high level, the low-side comparison circuit 332 determines that the switch voltage Vsw becomes higher than the reference voltage Vref. As a result, a low-side delay time determination signal SLt of a low level is output. The low-side comparison circuit 332 is switched to a high level at the timing at which the switch voltage Vsw becomes equal to the reference voltage Vref, i.e., after the first low-side delay time Tf1 has elapsed. To explain further, when the load Z is light, a low-side delay time determination signal SLt of a low level is output during the dead time period Dt (see FIG. 9).

The low-side AND circuit 334 receives the low-side command signal DIN_L of the high level and the low-side delay time determination signal SLt of the low level. As a result, the low-side AND circuit 334 outputs a second low-side control signal NL2 of a low level.

The first low-side control signal NL1 and the second low-side control signal NL2 are input to the low-side OR circuit 333. The second low-side control signal NL2 is at a low level at least during the dead time period Dt. Further, the first low-side control signal NL1 is switched to a high level after the low-side command signal DIN_L is switched to a high level and the first low-side delay time Tf1 has elapsed.

Therefore, the low-side OR circuit 333 outputs a low-side drive signal LG of a high level after the low-side command signal DIN_L is switched to a high level and the first low-side delay time Tf1 has elapsed.

In the switching power supply device A, the control circuit 3 is configured such that when the connected load Z is a light load, after a predetermined first low-side delay time Tf1 has elapsed, the low-side drive signal LG is switched to a high level, and the low-side switching element 2 is turned on. The low-side drive circuit 33 outputs a low-side drive signal LG that sets a length of the dead time period Dt to a predetermined first low-side delay time Tf1 when a light load Z is connected.

Next, the operation of the low-side drive circuit 33 when the load Z is a heavy load will be described. The first low-side control signal NL1 output by the low-side delay circuit 331 is the same as that when the load is a light load.

When the load Z is a heavy load, the switch voltage Vsw rapidly decreases due to the regenerative current of the inductor L1. Then, when the switch voltage Vsw becomes lower than the reference voltage Vref, the low-side comparison circuit 332 outputs a low-side delay time determination signal SLt of a high level. The switch voltage Vsw is maintained at a low level (here, 0 V) until the next rise after the dead time period Dt ends. Therefore, the low-side delay time determination signal SLt remains at a high level until the next rise.

The low-side AND circuit 334 receives the low-side command signal DIN_L of the high level and the low-side delay time determination signal SLt switched from a low level to a high level. As a result, the low-side AND circuit 334 outputs a second low-side control signal NL2 switched from a low level to a high level.

The first low-side control signal NL1 and the second low-side control signal NL2 are input to the low-side OR circuit 333. The second low-side control signal NL2 is switched from a low level to a high level when the switch voltage Vsw becomes equal to or lower than the reference voltage Vref. Further, the first low-side control signal NL1 is switched to a high level after the low-side command signal DIN_L is switched to a high level and the first low-side delay time Tf1 has elapsed.

As described above, in a case where the load Z is a heavy load, when the switch voltage Vsw becomes equal to or lower than the reference voltage Vref, the second low-side control signal NL2 is switched from a low level to a high level. A time from when the low-side command signal DIN_L is switched to a high level to when the switch voltage Vsw becomes equal to or lower than the reference voltage Vref is a second low-side delay time Tf2.

In a case where the load Z is heavier than when it is a light load, the second low-side delay time Tf2 becomes shorter than the first low-side delay time Tf1. Therefore, the term of the length of the dead time period Tf in the above-mentioned formula for the dead time loss Pd2 is substituted by the second low-side delay time Tf2 which is shorter than the first low-side delay time Tf1. This makes it possible to reduce the dead time loss Pd2.

As described above, since the control circuit 3 uses the low-side drive circuit 33, it is possible to reduce the dead time loss when the switch voltage Vsw of the switching power supply device A falls, regardless of the load Z.

As described above, in the switching power supply device A, the length of the dead time period Dt may be adjusted according to the load Z so as to reduce the dead time loss Pd1 when the switch voltage Vsw rises and the dead time loss Pd2 when the switch voltage Vsw falls.

### <First Modification>

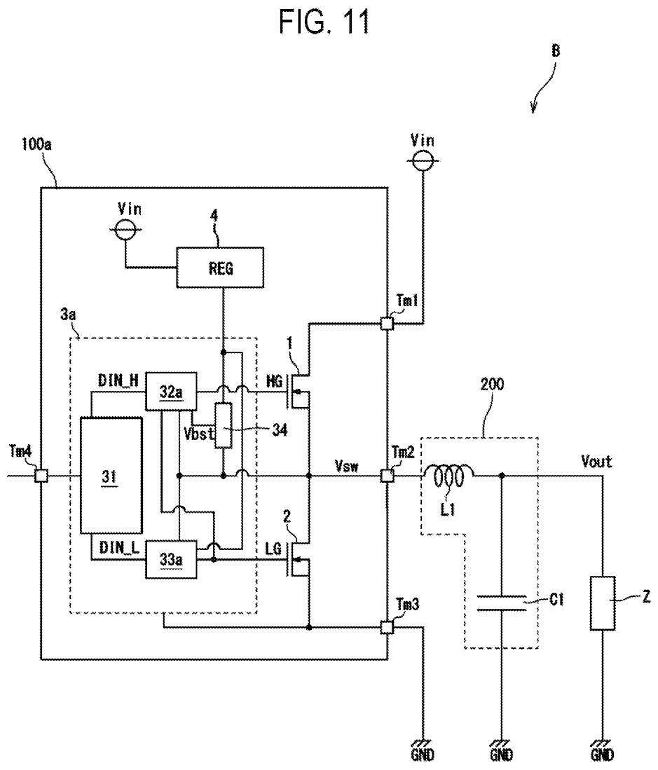

A first modification of the present disclosure will be described with reference to the drawings. FIG. 11 is a diagram showing an internal configuration of a switching power supply device B of a first modification. In the switching power supply device B of the first modification, the high-side drive circuit 32a and the low-side drive circuit 33a of the control circuit 3a are different from those of the control circuit 3 of the switching power supply device A. Except for this configuration, components of the switching power supply device B that are substantially the same as those of the switching power supply device A are designated by the same reference numerals, and detailed descriptions thereof will be omitted.

The control circuit 3a includes a high-side drive circuit 32a and a low-side drive circuit 33a. Details of the high-side drive circuit 32a will be described below.

<High-Side Drive Circuit 32a>

FIG. 12 is a diagram showing an internal configuration of a high-side drive circuit 32a of a modification. As shown in FIG. 12, a high-side command signal DIN_H, a low-side drive signal LG, a switch voltage Vsw, and a bootstrap voltage Vbst are input to the high-side drive circuit 32a.

As shown in FIG. 12, the high-side drive circuit 32a includes a high-side delay circuit 321, a second high-side OR circuit 324, an RS latch circuit 325, a high-side AND circuit 326, a first high-side control switching element 3281, a second high-side control switching element 3282, and inverting circuits 3291 and 3292.

The high-side delay circuit 321, the second high-side OR circuit 324, the RS latch circuit 325, and the high-side AND circuit 326 have the same configurations as those of the high-side drive circuit 32. Therefore, detailed descriptions of the configurations of these circuits will be omitted.

The first high-side control switching element 3281 is a p-channel MOS transistor. The bootstrap voltage Vbst supplied from the bootstrap circuit 34 is supplied to the source of the first high-side control switching element 3281 via a resistor 32R. In this modification, the bootstrap voltage Vbst supplied from the bootstrap circuit 34 is used. However, the present disclosure is not limited thereto. A wide range of voltages may be used to drive the high-side drive circuit 32a.

Further, the drain of the first high-side control switching element 3281 is connected in series to the second high-side control switching element 3282. A high-side command signal DIN_H is input to the gate of the first high-side control switching element 3281 via the inverting circuit 3291. The first high-side control switching element 3281 is controlled to be turned on when the high-side command signal DIN_H is at a high level, and controlled to be turned off when the high-side command signal DIN_H is at a low level.

The second high-side control switching element 3282 is an n-channel MOS transistor. A switch voltage Vsw is input to the drain of the second high-side control switching element 3282. The source of the second high-side control switching element 3282 is connected to the drain of the first high-side control switching element 3281. A low-side drive signal LG is input to the gate of the second high-side control switching element 3282 via the inverting circuit 3292. The second high-side control switching element 3282 is controlled to be turned on when the low-side drive signal LG is at a low level, and controlled to be turned off when the low-side drive signal LG is at a high level.

A high-side command signal DIN_H is input to the set terminal of the RS latch circuit 325. The voltage Vp2 at a connection point P2 between the source of the first high-side control switching element 3281 and the resistor 32R is input to the reset terminal of the RS latch circuit 325. The RS latch circuit 325 outputs a high-side delay time determination signal SHt of a high level when a high level signal is input to the set terminal and a low level signal is input to the reset terminal.

When the high-side command signal DIN_H is at a high level, the first high-side control switching element 3281 is turned on. Further, when the low-side drive signal LG is at a low level, the second high-side control switching element 3282 is turned on. At this time, when the switch voltage Vsw becomes 0 V, the voltage Vp2 at the connection point P2 is at a low level, and a high-side delay time determination signal SHt of a high level is output.

<Low-Side Drive Circuit 33a>

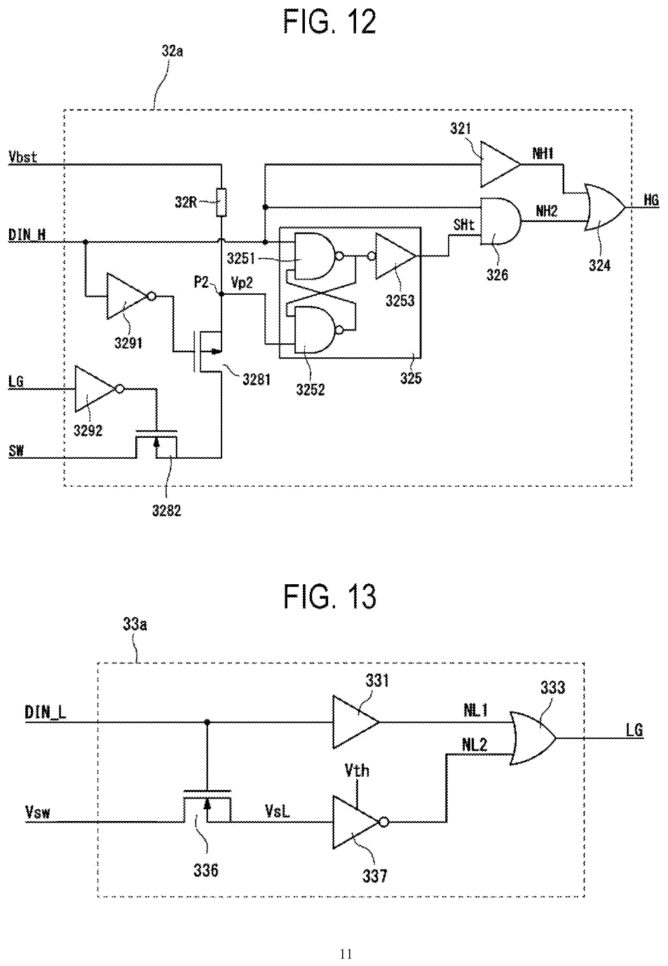

FIG. 13 is a diagram showing an internal configuration of a low-side drive circuit 33a of a modification. As shown in FIG. 13, a low-side command signal DIN_L and a switch voltage Vsw are input to the low-side drive circuit 33a.

As shown in FIG. 13, the low-side drive circuit 33a includes a low-side delay circuit 331, a low-side OR circuit 333, a low-side control switching element 336, and an inverter circuit 337.

The low-side delay circuit 331 and the low-side OR circuit 333 have the same configurations as those of the low-side drive circuit 33. Therefore, detailed descriptions of the configurations of these circuits will be omitted.

The low-side control switching element 336 is an n-channel MOS transistor. A switch voltage Vsw is input to the drain of the low-side control switching element 336. Further, the source of the low-side control switching element 336 is connected to the inverter circuit 337. A low-side command signal DIN_L is input to the gate of the low-side control switching element 336. The low-side control switching element 336 is in an on state when the low-side command signal DIN_L is at a high level.

The inverter circuit 337 is supplied with a source voltage VsL of the low-side control switching element 336. The inverter circuit 337 outputs a second low-side control signal NL2 of a high level when the source voltage VsL becomes equal to or lower than a threshold voltage Vth. The threshold voltage Vth is set to 0 V. The second low-side control signal NL2 is input to the low-side OR circuit 333 together with the first low-side control signal NL1.

<Operation of High-Side Drive Circuit 32a>

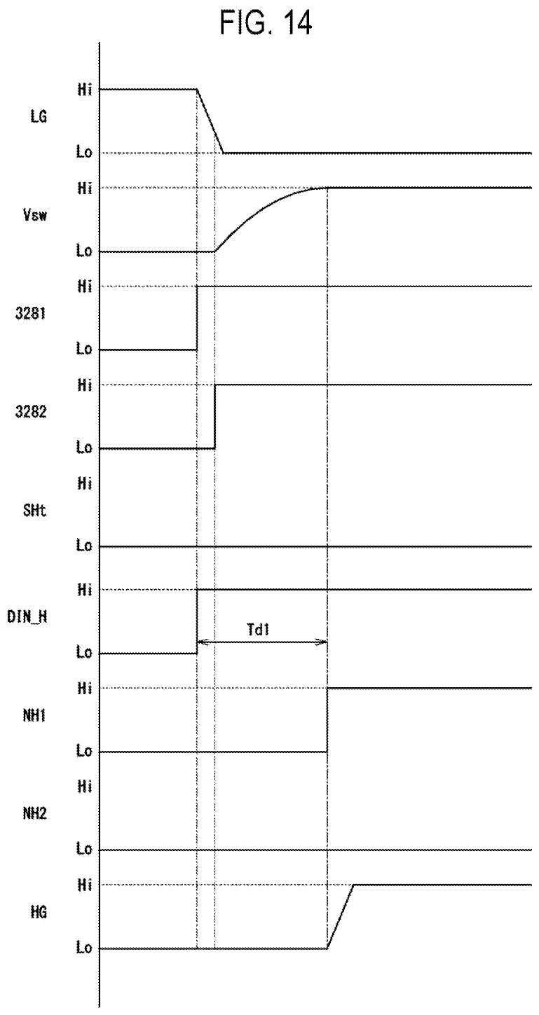

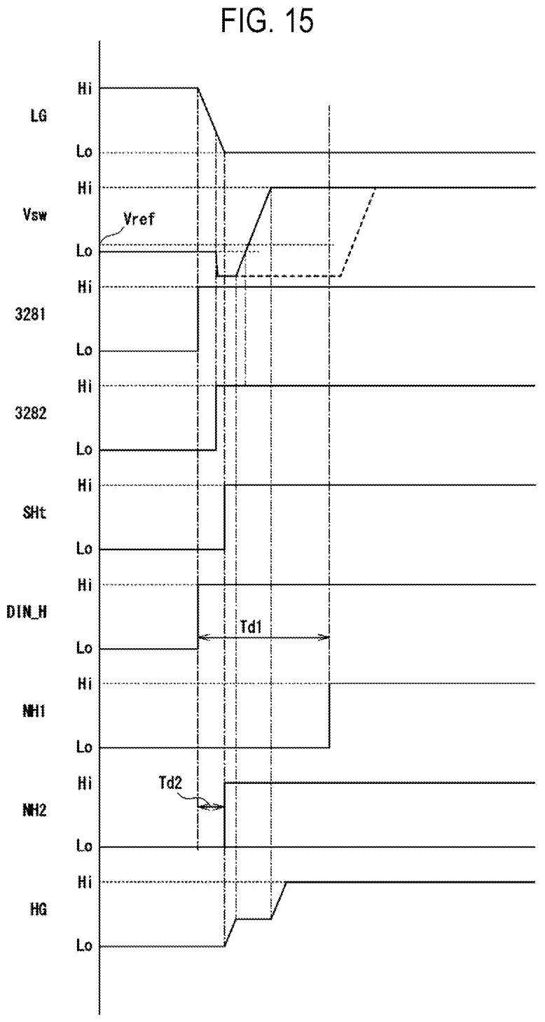

FIG. 14 is a timing chart of the high-side drive circuit 32a when the load Z is a light load. FIG. 15 is a timing chart of the high-side drive circuit 32a when the load Z is a heavy load. A detailed description of the operation of the high-side drive circuit 32a, which is the same as that of the high-side drive circuit 32, will be omitted.

As described above, in the high-side drive circuit 32a, the first high-side control switching element 3281 is maintained in an on state while the high-side command signal DIN_H is at a high level. On the other hand, when a load Z is a light load, the switch voltage increases sequentially over time. Therefore, the voltage Vp2 at the connection point P2 does not become a low level, and the RS latch circuit 325 constantly outputs a high-side delay time determination signal SHt of a low level. As a result, when the light load Z is connected, the second high-side control signal NH2 during the dead time is at a low level.

When a light load Z is connected, the high-side drive circuit 32a outputs a high-side drive signal HG of a high level that sets the dead time period Dt to a predetermined first high-side delay time Td1.

Further, in a case where a heavy load Z is connected, the second high-side control switching element 3282 is turned on when the low-side drive signal LG is switched to a low level. As shown in FIG. 15, at this time, the switch voltage Vsw is at a low level, and the voltage Vp2 at the connection point P2 is switched to a low level. Therefore, a high-side command signal DIN_H of a high level is input to the set terminal of the RS latch circuit 325, and a voltage Vp2 of a low level is input to the reset terminal.

As a result, the RS latch circuit 325 outputs a high-side delay time determination signal SHt of a high level. By outputting the high-side delay time determination signal SHt of the high level, the high-side AND circuit 326 outputs a second high-side control signal NH2 of a high level, and the second high-side OR circuit 324 outputs a high-side drive signal HG of a high level. By doing so, the dead time period Dt may be set to a second high-side delay time Td2, which is shorter than the first high-side delay time Td1. The switch voltage Vsw increases sequentially when the high-side switching element 1 is turned on. Therefore, the voltage Vp2 at the connection point P2 also rises. However, the high-side delay time determination signal SHt of the high level is maintained by inputting the voltage Vp2 of the high level to the reset terminal.

Even in a case where the high-side drive circuit 32a described above is used, the second high-side delay time Td2 becomes shorter than the first high-side delay time Td1 when the load Z is heavier than when it is a light load. Therefore, the term of the length of the dead time period Td in the formula for the dead time loss Pd1 described above is substituted by the second high-side delay time Td2, which is shorter than the first high-side delay time Td1. This makes it possible to reduce the dead time loss Pd1.

As described above, since the control circuit 3a uses the high-side drive circuit 32a, it is possible to reduce the dead time loss when the switch voltage Vsw of the switching power supply device B rises, regardless of the load Z.

<Operation of Low-Side Drive Circuit 33a>

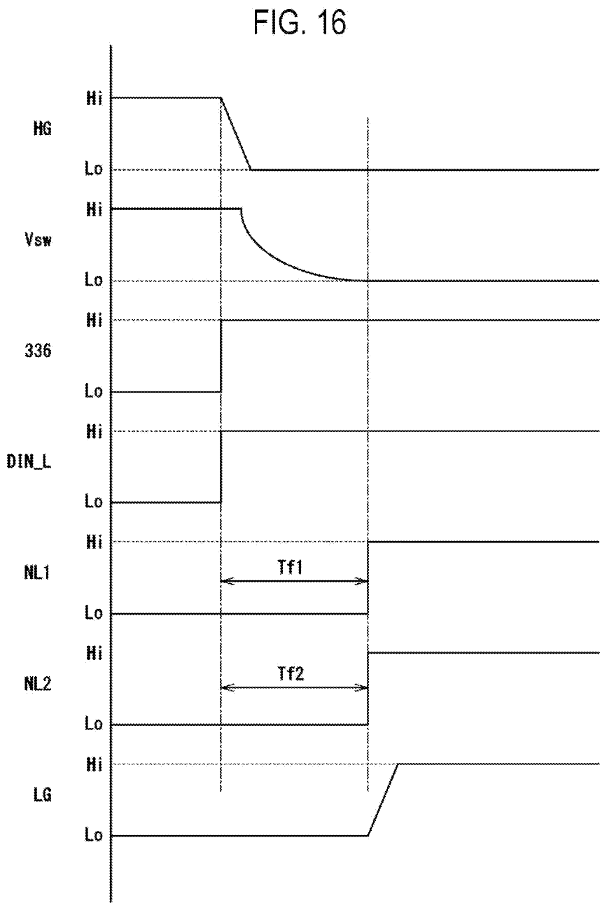

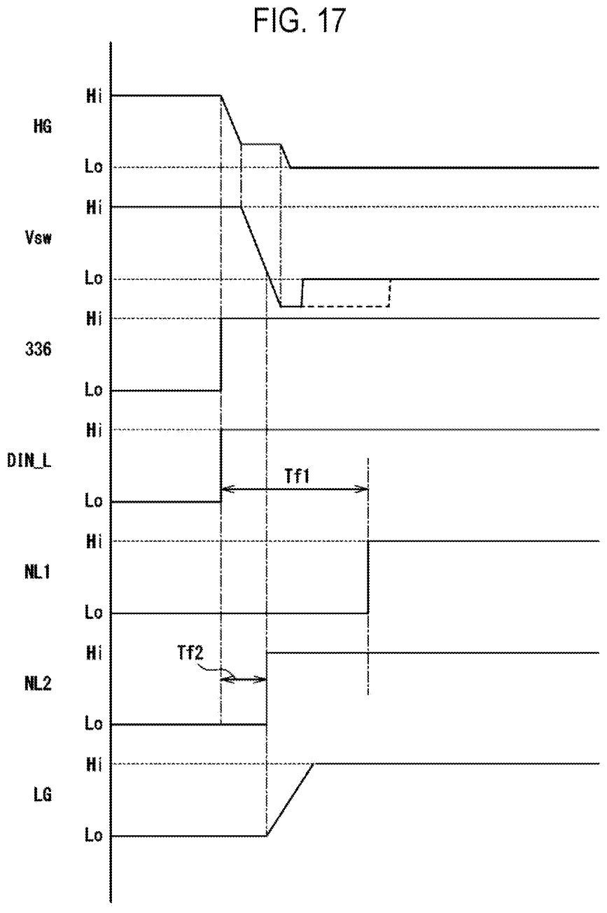

FIG. 16 is a timing chart of the low-side drive circuit 33a when the load Z is a light load. FIG. 17 is a timing chart of the low-side drive circuit 33a when the load Z is a heavy load. A detailed description of the operation of the low-side drive circuit 33a, which is the same as that of the low-side drive circuit 33, will be omitted.

As described above, in the low-side drive circuit 33a, the low-side control switching element 336 is maintained in an on state while the low-side command signal DIN_L is at a high level. On the other hand, when the load Z is a light load, the switch voltage Vsw gradually decreases over time. Therefore, during the dead time period Dt, the source voltage VsL of the low-side control switching element 336 becomes higher than the threshold voltage Vth of the inverter circuit 337. The inverter circuit 337 outputs a second low-side control signal NL2 of a low level.

Then, the switch voltage Vsw becomes 0 V when the first low-side delay time Tf1 has elapsed after the low-side command signal DIN_L is switched from the low level to the high level. Thus, the source voltage VsL of the low-side control switching element 336 becomes equal to or lower than the threshold voltage Vth of the inverter circuit 337. As a result, the inverter circuit 337 outputs a second low-side control signal NL2 of a high level. That is, the second low-side control signal NL2 is switched from the low level to the high level at the same timing as the first low-side control signal NL1. The low-side drive circuit 33a outputs a low-side drive signal LG which is adjusted such that the length of the dead time period Dt becomes equal to the predetermined first low-side delay time Tf1.

Next, the operation of the low-side drive circuit 33a when the load Z is a heavy load will be described. The first low-side control signal NL1 output by the low-side delay circuit 331 is the same as that when the load is a light load.

The switch voltage Vsw rapidly decreases and first becomes 0 V or less. When the switch voltage Vsw becomes 0 V or less, the inverter circuit 337 outputs a second low-side control signal NL2 of a high level.

The low-side OR circuit 333 outputs a high-side drive signal which is switched from a low level to a high level when the first low-side control signal NL1 is switched to a high level or the second low-side control signal NL2 is switched to a high level.

As described above, in a case where the load Z is the heavy load, when the source voltage VsL is equal to or lower than the threshold voltage Vth of the inverter circuit 337, the inverter circuit 337 outputs a second low-side control signal NL2 of a high level. The time from when the low-side command signal DIN_L is switched to a high level to when the switch voltage Vsw becomes lower than or equal to the threshold voltage Vth of the inverter circuit 337 is a second low-side delay time Tf2.

In a case where the load Z is heavier than when it is a light load, the second low-side delay time Tf2 becomes shorter than the first low-side delay time Tf1. Therefore, the term of the length of the dead time period Tf in the above-mentioned formula for the dead time loss Pd2 is substituted by the second low-side delay time Tf2 which is shorter than the first low-side delay time Tf1. This makes it possible to reduce the dead time loss Pd2.

As described above, since the control circuit 3 uses the low-side drive circuit 33a, it is possible to reduce the dead time loss when the switch voltage Vsw of the switching power supply device B falls, regardless of the load Z.

As described above, in the switching power supply device B, the length of the dead time period Dt may be adjusted according to the load Z so as to reduce the dead time losses Pd1 when the switch voltage Vsw rises and the dead time loss Pd2 when the switch voltage Vsw falls.

In the configuration of the present disclosure, an n-channel MOS transistor is used as the high-side switching element, but the present disclosure is not limited thereto. A p-channel MOS transistor may be used. In this case, the bootstrap circuit 34 may be omitted. In the first modification, the input voltage Vin or a voltage generated by a separate power supply circuit may be supplied to the terminal to which the bootstrap voltage Vbst is supplied.

In the switching power supply devices A and B, it is possible to execute a nano-pulse control that may realize a high step-down ratio (e.g., conversion from 48 V to 3 V to 5 V) at high frequencies to improve a power density. Further, since the switching power supplies A and B operate at high frequencies, such that dead time losses are reduced, it is possible to reduce losses. The dead time losses are effective in reducing losses even in a Si-based device. However, in the GaN device used when performing a high-frequency and large-current switching control, a forward voltage Vf (e.g., about 2.5 V) larger than a Si-based forward voltage Vf (e.g., about 0.7 V) is generated. Therefore, when using the GaN device, it is possible to further enhance the effect of reducing losses as compared with the case where the Si-based device is used.

### <Second Modification>

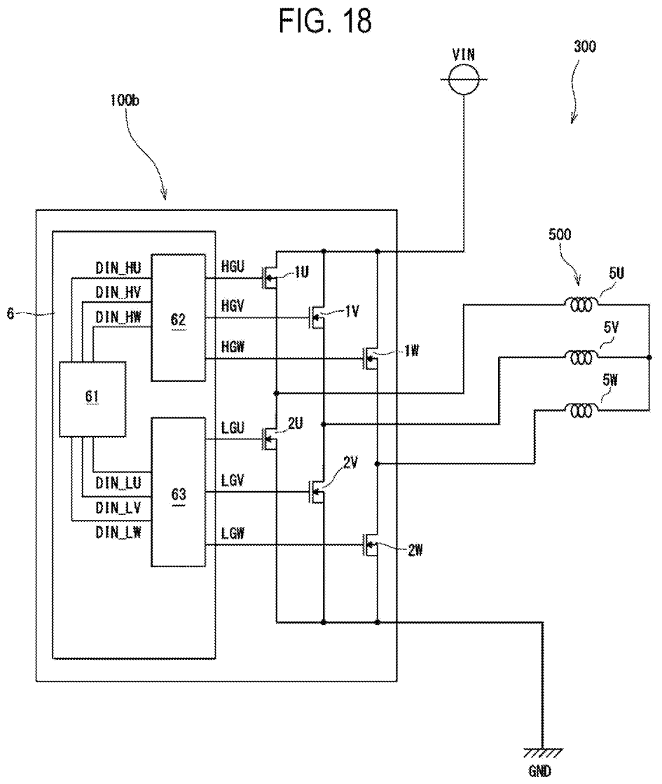

FIG. 18 is an overall configuration diagram of a motor drive device 300 using a semiconductor device 100b of a second modification. The semiconductor device 100b of the motor drive device 300 shown in FIG. 18 is used as a motor drive circuit configured to drive a DC brushless motor 500.

The DC brushless motor 500 includes a U-phase coil 5U, a V-phase coil 5V, and a W-phase coil 5W. The semiconductor device 100b includes a U-phase high-side switching element 1U, a U-phase low-side switching element 2U, a V-phase high-side switching element 1V, a V-phase low-side switching element 2V, a W-phase high-side switching element 1W, a W-phase low-side switching element 2W, and a control circuit 6.

One set of the U-phase high-side switching element 1U and the U-phase low-side switching element 2U has the same configuration as the high-side switching element 1 and the low-side switching element 2 of the semiconductor device 100, and is connected to the U-phase coil 5U. Similarly, one set of the V-phase high-side switching element 1V and the V-phase low-side switching element 2V has the same configuration as the high-side switching element 1 and the low-side switching element 2 of the semiconductor device 100, and is connected to the V-phase coil 5V. One set of the W-phase high-side switching element 1W and the W-phase low-side switching element 2W has the same configuration as the high-side switching element 1 and the low-side switching element 2 of the semiconductor device 100b, and is connected to the W-phase coil 5W. That is, the semiconductor device 100b includes three sets of the high-side switching element 1 and the low-side switching element 2, in which the high-side switching element 1 and the low-side switching element 2 included in the semiconductor device 100 constitute one set.

The control circuit 6 includes a signal generation circuit 61, a high-side drive circuit 62, and a low-side drive circuit 63. The signal generation circuit 61 supplies high-side command signals DIN_HU, DIN_HV, and DIN_HW to the high-side drive circuit 62. Further, the signal generation circuit 61 supplies low-side command signals DIN_LU, DIN_LV, and DIN_LW to the low-side drive circuit 63.

The high-side drive circuit 62 has the same configuration as the above-described high-side drive circuit 32 or 32a, and supplies high-side drive signals HGU, HGV, and HGW generated from the high-side command signals DIN_HU, DIN_HV, and DIN_HW to the high-side switching elements 1U, 1V, and 1W. The high-side drive circuit 62 generates the high-side drive signals HGU, HGV, and HGW such that a dead time period is formed at the rise of the voltage supplied to each coil from the high-side switching element and low-side switching element of each phase.

The low-side drive circuit 63 has the same configuration as the above-described low-side drive circuit 33 or 33a, and supplies the low-side drive signals LGU, LGV, and LGW generated from the low-side command signals DIN_LU, DIN_LV, and DIN_LW to the low-side switching elements 2U, 2V, and 2W. The low-side drive circuit 63 generates low-side drive signals LGU, LGV, and LGW such that a dead time period is formed at the fall of the voltage supplied to each coil from the high-side switching element and low-side switching element of each phase.

### <Application>

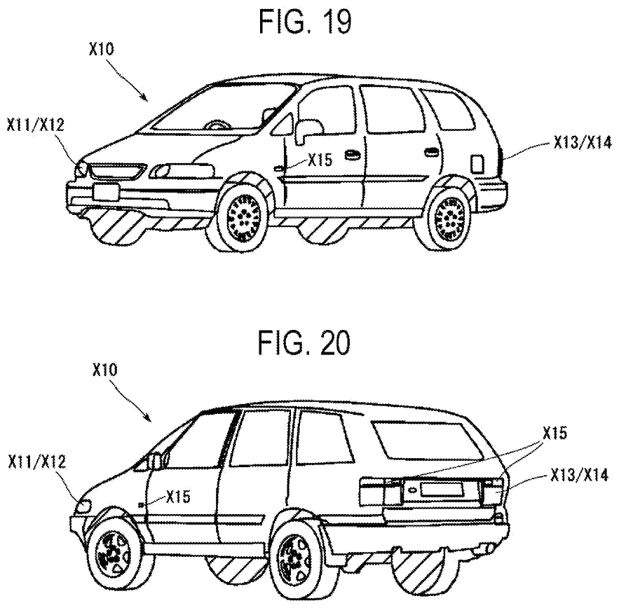

The switching power supply device A using the semiconductor device 100 described above may be a light emitting device that adopts LEDs as a load Z. For example, as shown in FIGS. 19 and 20, such a light emitting device may be suitably used as a light emitting device such as a headlight (including a high beam, a low beam, a small lamp, a fog lamp, or the like as appropriate) X11, a light source for day/night driving (DRL) X12, a tail lamp X13 (including a small lamp, a back lamp, or the like as appropriate), a stop lamp X14, and a turn lamp X15 of a vehicle X10.

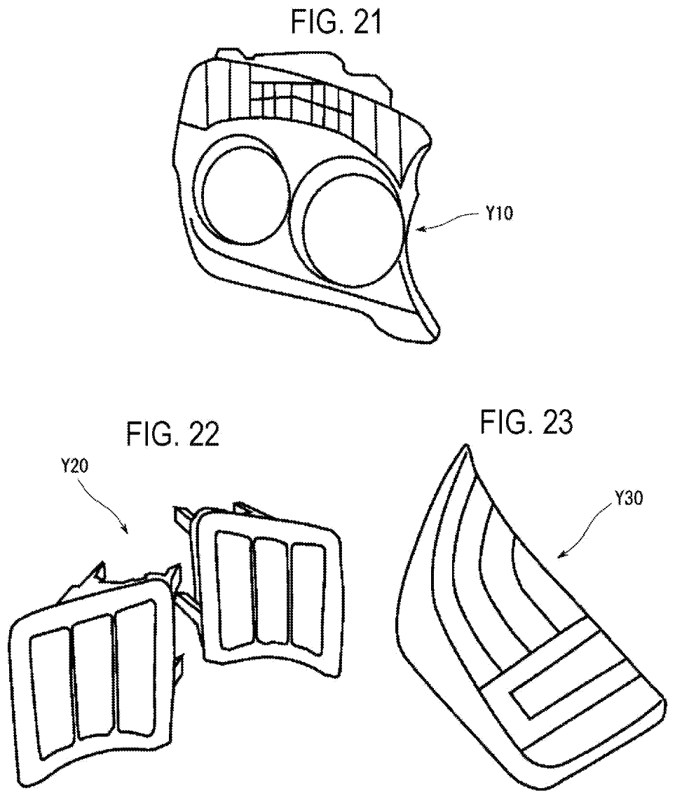

The light emitting device described above may be provided as a light emitting device of a module (such as an LED headlight module Y10 shown in FIG. 21, an LED turn lamp module Y20 shown in FIG. 22, or an LED rear lamp module Y30 shown in FIG. 23). Further, the semiconductor device 100 may be provided in the form of a light emission control device configured to control light emission of LEDs.

Further, the semiconductor device used in the light emitting device is not limited to the semiconductor device 100, and the semiconductor device 100a may be used.

### <Others>

The above-described embodiments should be considered to be exemplary in all respects and not limitative. The technical scope of the present disclosure is defined by the claims rather than the above description of the embodiments. It should be understood that all changes that come within the meaning and range of equivalents of the claims are included in the technical scope of the present disclosure.

Although the PWM signal is used in the above-described embodiments, a pulse signal other than the PWM signal may be used instead of the PWM signal. Examples of the pulse signal other than the PWM signal include a pulse frequency modulation (PFM) signal and a pulse density modulation (PDM) signal.

The semiconductor device (100 or 100a) described above, includes: a high-side switching element (1); a low-side switching element (2) connected in series to the high-side switching element (1); and a control circuit (3 or 3a) configured to be capable of controlling on/off operations of the high-side switching element (1) and the low-side switching element (2) in a complementary manner, the semiconductor device (100) is configured to output an output voltage (Vout) generated from a voltage (Vsw) at a connection point (P1) between the high-side switching element (1) and the low-side switching element (2), and the control circuit (3 or 3a) is configured to control a dead time (Dt) during which both the high-side switching element (1) and the low-side switching element (2) are controlled to be turned off, based on the voltage (Vsw) at the connection point (P1), such that the dead time (Dt) is shorter when a load (Z) that is supplied with the output voltage (Vout) is heavy than when the load (Z) is light (first configuration).

In the semiconductor device (100 or 100a) of the first configuration, the control circuit (3 or 3a) is configured to control a time from when the high-side switching element (1) is turned off to when the low-side switching element (2) is turned on, such that the time is shorter when the load (Z) is heavy than when the load (Z) is light (second configuration).

In the semiconductor device (100 or 100a) of the second configuration, the control circuit (3 or 3a) is configured to generate a first low-side control signal (NL1) obtained by delaying a low-side command signal (DIN_L) which is in a first state when the high-side switching element (1) is turned off, by a certain period (Tf1), and a second low-side control signal (NL2) which is in the first state when the low-side command signal (DIN_L) of the first state is input and the voltage (Vsw) at the connection point (P1) is lower than a predetermined voltage (Vref), and is configured to turn on the low-side switching element (2) when at least one selected from the group of the first low-side control signal (NL1) and the second low-side control signal (NL2) is in the first state (third configuration).

In the semiconductor device of the second configuration or the third configuration, the control circuit (3) includes: a low-side delay circuit (331) configured to generate a first low-side control signal (NL1) obtained by delaying a low-side command signal (DIN_L) which is in a first state when the high-side switching element (1) is turned off, by a certain period (Tf1); a low-side comparison circuit (332) configured to generate a low-side delay time determination signal (SLt) which is in the first state when the voltage (Vsw) at the connection point (P1) is lower than a predetermined voltage (Vref); a low-side AND circuit (334) configured to generate a second low-side control signal (NL2) which is in the first state when both the low-side command signal (DIN_L) and the low-side delay time determination signal (SHt) are in the first state; and a low-side OR circuit (333) configured to generate a low-side drive signal (LG) which is in the first state to control the low-side switching element (2) to be turned on when at least one selected from the group of the first low-side control signal (NL1) and the second low-side control signal (NL2) is in the first state (fourth configuration).

In the semiconductor device of the second configuration or the third configuration, the control circuit (3a) includes: a low-side delay circuit (331) configured to generate a first low-side control signal (NL1) obtained by delaying a low-side command signal (DIN_L) which is in a first state when the high-side switching element (1) is turned off, by a certain period (Tf1); a low-side control switching element (336) configured such that the voltage (Vsw) at the connection point (P1) is input to an input terminal of the low-side control switching element (336) and the low-side command signal (DIN_L) is input to a control terminal of the low-side control switching element (336); an inverter circuit (337) connected to an output terminal of the low-side control switching element (336) and configured to generate a second low-side control signal (NL2) when a voltage (VsL) of a signal output from the low-side control switching element (336) is lower than a predetermined voltage (Vth); and a low-side OR circuit (333) configured to generate a low-side drive signal (LG) which is in the first state to control the low-side switching element (2) to be turned on when at least one selected from the group of the first low-side control signal (NL1) and the second low-side control signal (NL2) is in the first state (fifth configuration).

In the semiconductor device (100 or 100a) of any one of the first to fifth configurations, the control circuit (3 or 3a) is configured to control a time from when the low-side switching element (2) is turned off to when the high-side switching element (1) is turned on such that the time is shorter when the load (Z) is heavy than when the load (Z) is light (sixth configuration).

In the semiconductor device (100 or 100a) of the sixth configuration, the control circuit (3 or 3a) is configured to generate a first high-side control signal (NH1) obtained by delaying a high-side command signal (DIN_H) which is in a first state when the low-side switching element (2) is turned off, by a certain period (Td1), and a second high-side control signal (NH2) which is in the first state when a low-side drive signal (LG) that controls the low-side switching element (2) to be turned on is input and the voltage (Vsw) at the connection point (P1) is lower than a predetermined voltage (Vref), and is configured to turn on the high-side switching element (1) when at least one selected from the group of the first high-side control signal (NH1) and the second high-side control signal (NH2) is in the first state (seventh configuration).

In the semiconductor device (100) of the sixth configuration or the seventh configuration, the control circuit (3) includes: a high-side delay circuit (321) configured to generate a first high-side control signal (NH1) obtained by delaying a high-side command signal (DIN_H) which is in a first state when the low-side switching element (2) is turned off, by a certain period (Td1); a high-side comparison circuit (322) configured to generate a comparison result signal (SHc) which is in the first state when the voltage (Vsw) at the connection point (P1) is higher than a predetermined voltage (Vref); a first high-side OR circuit (323) configured to generate a reset signal (SHr) which is in the first state when at least one selected from the group of a low-side drive signal (LG) that controls the low-side switching element (2) to be turned on and the comparison result signal (SHc) is in the first state; an RS latch circuit (325) configured such that the high-side command signal (DIN_H) is input to a set terminal of the RS latch circuit (325) and the reset signal (SHr) is input to a reset terminal of the RS latch circuit (325) to generate a high-side delay time determination signal (SHt); a high-side AND circuit (326) configured to generate a second high-side control signal (NH2) which is in the first state when both the high-side command signal (DIN_H) and the high-side delay time determination signal (SHt) are in the first state; and a second high-side OR circuit (324) configured to generate a high-side drive signal (HG) which is in the first state when at least one selected from the group of the first high-side control signal (NH1) and the second high-side control signal (NH2) is in the first state, so as to control the high-side switching element (1) to be turned on (eighth configuration).

In the semiconductor device (100a) of the sixth configuration or the seventh configuration, the control circuit (3a) includes: a high-side delay circuit (321) configured to generate a first high-side control signal (NH1) obtained by delaying a high-side command signal (DIN_H) which is in a first state when the low-side switching element (2) is turned off, by a certain period (Td1); a first high-side control switching element (3281) configured such that a power supply voltage (Vbst) for driving the control circuit (3a) is input to the first high-side control switching element (3281) and an inverted high-side command signal (DIN_H) is input to a control terminal of the first high-side control switching element (3281); a second high-side control switching element (3282) connected in series to the first high-side control switching element (3281) and configured such that the voltage (Vsw) at the connection point (P1) is input to an input terminal of the second high-side control switching element (3282) and a signal obtained by inverting a low-side drive signal (LG) that controls the low-side switching element (2) to be turned on is input to a control terminal of the second high-side control switching element (3282); an RS latch circuit (325) configured such that the high-side command signal (DIN_H) is input to a set terminal of the RS latch circuit (325) and a voltage (Vp2) at an input terminal (P2) of the first high-side control switching element (3281) is input to a reset terminal of the RS latch circuit (325) to generate a high-side delay time determination signal (SHt); a high-side AND circuit (326) configured to generate a second high-side control signal (NH2) which is in the first state when both the high-side command signal (DIN_H) and the high-side delay time determination signal (SHt) are in the first state; and a high-side OR circuit (324) configured to generate a high-side drive signal (HG) which is in the first state when at least one selected from the group of the first high-side control signal (NH1) and the second high-side control signal (NH2) is in the first state, so as to control the high-side switching element (1) to be turned on (ninth configuration).

In the semiconductor device (100 or 100a) of any one of the first to ninth configurations, at least one selected from the group of the high-side switching element (1) and the low-side switching element (2) is a GaN semiconductor (tenth configuration).

In the semiconductor device (100 or 100a) of any one of the first to tenth configurations, at least one selected from the group of the high-side switching element (1) and the low-side switching element (2) is a Si-based semiconductor (eleventh configuration).

A DC/DC converter includes the semiconductor device (100 or 100a) of any one of the first to eleventh configurations (twelfth configuration).

A switching power supply device (A or B) includes the DC/DC converter of the twelfth configuration (thirteenth configuration).

A vehicle (X10) includes the semiconductor device (100 or 100a) of any one of the first to eleventh configurations (fourteenth configuration).

A motor drive device includes: a plurality of sets of the high-side switching element (1U, 1V or 1W) and the low-side switching element (2U, 2V or 2W) included in the semiconductor device (100 or 100b) of any one of the first to eleventh configurations, wherein the voltage at the connection point between the high-side switching element (1U, 1V or 1W) and the low-side switching element (2U, 2V or 2W) is capable of being supplied to a motor (500) (fifteenth configuration).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a high-side switching element;
a low-side switching element connected in series to the high-side switching element; and
a control circuit configured to be capable of controlling on/off operations of the high-side switching element and the low-side switching element in a complementary manner,
wherein the semiconductor device is configured to output an output voltage generated from a voltage at a connection point between the high-side switching element and the low-side switching element, and
wherein the control circuit is configured to control a dead time during which both the high-side switching element and the low-side switching element are controlled to be turned off, based on the voltage at the connection point, such that the dead time is shorter when a load that is supplied with the output voltage is heavy than when the load is light.

2. The semiconductor device of claim 1, wherein the control circuit is configured to control a time from when the high-side switching element is turned off to when the low-side switching element is turned on such that the time is shorter when the load is heavy than when the load is light.

3. The semiconductor device of claim 2, wherein the control circuit is configured to generate a first low-side control signal obtained by delaying a low-side command signal which is in a first state when the high-side switching element is turned off, by a certain period, and a second low-side control signal which is in the first state when the low-side command signal of the first state is input and the voltage at the connection point is lower than a predetermined voltage, and is configured to turn on the low-side switching element when at least one selected from the group of the first low-side control signal and the second low-side control signal is in the first state.

4. The semiconductor device of claim 2, wherein the control circuit includes:
a low-side delay circuit configured to generate a first low-side control signal obtained by delaying a low-side command signal which is in a first state when the high-side switching element is turned off, by a certain period;
a low-side comparison circuit configured to generate a low-side delay time determination signal which is in the first state when the voltage at the connection point is lower than a predetermined voltage;
a low-side AND circuit configured to generate a second low-side control signal which is in the first state when both the low-side command signal and the low-side delay time determination signal are in the first state; and
a low-side OR circuit configured to generate a low-side drive signal which is in the first state to control the low-side switching element to be turned on when at least one selected from the group of the first low-side control signal and the second low-side control signal is in the first state.

5. The semiconductor device of claim 2, wherein the control circuit includes:
a low-side delay circuit configured to generate a first low-side control signal obtained by delaying a low-side command signal which is in a first state when the high-side switching element is turned off, by a certain period;
a low-side control switching element configured such that the voltage at the connection point is input to an input terminal of the low-side control switching element and the low-side command signal is input to a control terminal of the low-side control switching element;
an inverter circuit connected to an output terminal of the low-side control switching element and configured to generate a second low-side control signal when a voltage of a signal output from the low-side control switching element is lower than a predetermined voltage; and
a low-side OR circuit configured to generate a low-side drive signal which is in the first state to control the low-side switching element to be turned on when at least one selected from the group of the first low-side control signal and the second low-side control signal is in the first state.

6. The semiconductor device of claim 1, wherein the control circuit is configured to control a time from when the low-side switching element is turned off to when the high-side switching element is turned on such that the time is shorter when the load is heavy than when the load is light.

7. The semiconductor device of claim 6, wherein the control circuit is configured to generate a first high-side control signal obtained by delaying a high-side command signal which is in a first state when the low-side switching element is turned off, by a certain period, and a second high-side control signal which is in the first state when a low-side drive signal that controls the low-side switching element to be turned on is input and the voltage at the connection point is lower than a predetermined voltage, and is configured to turn on the high-side switching element when at least one selected from the group of the first high-side control signal and the second high-side control signal is in the first state.

8. The semiconductor device of claim 6, wherein the control circuit includes:
a high-side delay circuit configured to generate a first high-side control signal obtained by delaying a high-side command signal which is in a first state when the low-side switching element is turned off, by a certain period;
a high-side comparison circuit configured to generate a comparison result signal which is in the first state when the voltage at the connection point is higher than a predetermined voltage;
a first high-side OR circuit configured to generate a reset signal which is in the first state when at least one selected from the group of a low-side drive signal that controls the low-side switching element to be turned on and the comparison result signal is in the first state;
an RS latch circuit configured such that the high-side command signal is input to a set terminal of the RS latch circuit and the reset signal is input to a reset terminal of the RS latch circuit to generate a high-side delay time determination signal;
a high-side AND circuit configured to generate a second high-side control signal which is in the first state when both the high-side command signal and the high-side delay time determination signal are in the first state; and
a second high-side OR circuit configured to generate a high-side drive signal which is in the first state when at least one selected from the group of the first high-side control signal and the second high-side control signal is in the first state, so as to control the high-side switching element to be turned on.

9. The semiconductor device of claim 6, wherein the control circuit includes:
a high-side delay circuit configured to generate a first high-side control signal obtained by delaying a high-side command signal which is in a first state when the low-side switching element is turned off, by a certain period;
a first high-side control switching element configured such that a power supply voltage for driving the control circuit is input to the first high-side control switching element and an inverted high-side command signal is input to a control terminal of the first high-side control switching element;
a second high-side control switching element connected in series to the first high-side control switching element and configured such that the voltage at the connection point is input to an input terminal of the second high-side control switching element and a signal obtained by inverting a low-side drive signal that controls the low-side switching element to be turned on is input to a control terminal of the second high-side control switching element;
an RS latch circuit configured such that the high-side command signal is input to a set terminal of the RS latch circuit and a voltage at an input terminal of the first high-side control switching element is input to a reset terminal of the RS latch circuit to generate a high-side delay time determination signal;
a high-side AND circuit configured to generate a second high-side control signal which is in the first state when both the high-side command signal and the high-side delay time determination signal are in the first state; and
a high-side OR circuit configured to generate a high-side drive signal which is in the first state when at least one selected from the group of the first high-side control signal and the second high-side control signal is in the first state, so as to control the high-side switching element to be turned on.

10. The semiconductor device of claim 1, wherein at least one selected from the group of the high-side switching element and the low-side switching element is a GaN semiconductor.

11. The semiconductor device of claim 1, wherein at least one selected from the group of the high-side switching element and the low-side switching element is a Si-based semiconductor.

12. A DC/DC converter comprising the semiconductor device of claim 1.

13. A switching power supply device comprising the DC/DC converter of claim 12.

14. A vehicle comprising the semiconductor device of claim 1.

15. A motor drive device, comprising:
a plurality of sets of the high-side switching element and the low-side switching element included in the semiconductor device of claim 1,
wherein the voltage at the connection point between the high-side switching element and the low-side switching element is capable of being supplied to a motor.
